(19) United States
(12) Patent Application Publication
(10) Pub. No.: US 2021/0259101 A1
(43) Pub. Date: Aug. 19, 2021

(54) INFORMATION PROCESSING APPARATUS AND METHOD OF MANUFACTURING INFORMATION PROCESSING APPARATUS

(71) Applicant: PANASONIC INTELLECTUAL PROPERTY MANAGEMENT CO., LTD., Osaka (JP)

(72) Inventors: Takeyuki SASAKI, Kanagawa (JP); Kyohei KIDA, Kanagawa (JP)

(73) Assignee: PANASONIC INTELLECTUAL PROPERTY MANAGEMENT CO., LTD., Osaka (JP)

(21) Appl. No.: 17/116,752

(22) Filed: Dec. 9, 2020

(30) Foreign Application Priority Data
Feb. 13, 2020 (JP) 2020-022597

(51) Int. Cl. H05K 1/02; H01R 13/52; H01R 12/73; H05K 1/18; G06K 7/00

(52) U.S. Cl. CPC H05K 1/0275; H01R 13/5213; H01R 12/73; H05K 1/181; H05K 2201/0999; H05K 2201/10151; H05K 2201/10189; H05K 2201/09063; G06K 7/0056

(57) ABSTRACT

An information processing apparatus includes a circuit board having an electronic device, a first contact and a pin hole; a cover covering the electronic device and the first contact on the circuit board; and a case accommodating the circuit board and the cover. The cover has a second contact being in contact with the first contact, a tampering detection wiring for tampering detection of the cover connected to the second contact, a through hole absorbing dimensional tolerance, and a positioning pin corresponding to the pin hole of the circuit board. The cover is attached to a back face of the case by inserting a predetermined screw into the through hole, and is positioned by inserting the positioning pin into the pin hole on the circuit board.

### CROSS-REFERENCE TO RELATED APPLICATIONS

This application is based on and claims priority under 35 USC 119 from Japanese Patent Application No. 2020-022597 filed on Feb. 13, 2020, the contents of which are incorporated herein by reference.

### TECHNICAL FIELD

The present disclosure relates to an information processing apparatus and a method of manufacturing an information processing apparatus.

### BACKGROUND ART

In recent years, the introduction of settlement terminals that provide electronic settlements to users has been promoted in stores and commercial facilities. The settlement terminals handle secret information such as a credit card number, identification information of an IC card, personal information of a user, and a secret key used for encrypting information in the internal processing. Therefore, the information processing apparatus that executes the internal processing of the settlement terminal includes a tamperproof mechanism for resisting a physical attack (tamper) from the outside for the purpose of analyzing or falsifying secret information.

Patent Literature 1 discloses an information processing apparatus including first and second circuit boards disposed on a device main body in a state of being separated from each other, electronic components disposed on opposite faces of the first and second circuit boards respectively, a shielding member surrounding an outer periphery of the first and second circuit boards, and a tamper detection circuit. The tamper detection circuit erases data in the memory when a hole is formed in the shielding member on which a detection line is formed with a drill and the like. As a result, the secret information in the memory is prevented from being analyzed.

Patent Literature 2 discloses a data storage device including sufficiently thin electric wires which are wired so as to cover almost the entire face of a housing at a sufficiently narrow interval, a detection means that detects disconnection of the electric wire, and a memory provided in the housing. When the disconnection of the electric wire is detected, the detection unit erases the data in the memory. As a result, the secret information in the memory is prevented from being analyzed.

### CITATION LIST

### Patent Literature

Patent Literature 1: JP-A-2013-3979

Patent Literature 2: JP-A-2008-33593

### SUMMARY OF INVENTION

As described above, the information processing apparatus which handles secret information is required to have physical tamper proof. An object of the present disclosure is to provide an information processing apparatus with improved tamper proof and a method of manufacturing the same.

An information processing apparatus according to the present disclosure includes a circuit board that has an electronic device, a first contact and a pin hole; a cover that covers the electronic device and the first contact on the circuit board; and a case that accommodates the circuit board and the cover. The cover includes a second contact that is in contact with the first contact, a tampering detection wiring that is connected to the second contact and that is a wiring for tampering detection of the cover, a through hole that absorbs dimensional tolerance, and a positioning pin that corresponds to the pin hole of the circuit board. The cover is attached to a back face of the case by inserting a predetermined screw into the through hole, and is positioned by inserting the positioning pin into the pin hole on the circuit board.

A method of manufacturing an information processing apparatus is provided according to the present disclosure. The information processing apparatus includes a circuit board that has an electronic device, a first contact and a pin hole, a cover that covers the electronic device and the first contact on the circuit board, a second contact that is provided on the cover and is contact with the first contact, a tamper detection wiring that is provided on the cover and that is a wiring for tampering detection connected to the second contact, a through hole that is provided on the cover and that absorbs dimensional tolerance, a positioning pin that is provided on the cover and that corresponds to the pin hole of the circuit board, and a case that accommodates the circuit board and the cover. The method includes the steps of: inserting the positioning pin into the pin hole of the circuit board; and attaching the cover to a back face of the case by inserting a predetermined screws into the through holes

According to the present disclosure, an information processing apparatus and a method of manufacturing the same can be provided.

### BRIEF DESCRIPTION OF DRAWINGS

FIGS. 1A to 1C are views showing a configuration example of a settlement terminal according to the present embodiment, FIG. 1A is a top view, FIG. 1B is a side view, and FIG. 1C is a front view.

FIG. 2 is a view showing a configuration example of the information processing apparatus according to the present embodiment, and is an exploded perspective view of the information processing apparatus as viewed obliquely from above.

FIG. 3 is a view showing a configuration example of the information processing apparatus according to the present embodiment, and is an exploded perspective view of the information processing apparatus as viewed obliquely from below.

FIG. 4 is a view showing an example of attachment of a protective cover to a case using a stepped screw.

### DESCRIPTION OF EMBODIMENTS

Hereinafter, embodiments of the present disclosure will be described in detail with reference to the drawings. However, unnecessarily detailed description may be omitted. For example, detailed description of well-known matters and repeated description of substantially the same configurations may be omitted. This is to avoid unnecessary redundancy in the following description and to facilitate understanding of those skilled in the art. The accompanying drawings and the following description are provided for those skilled in the art to fully understand the present disclosure, and are not intended to limit the subject matter of the claims.

### Present Embodiment

### Settlement Terminal

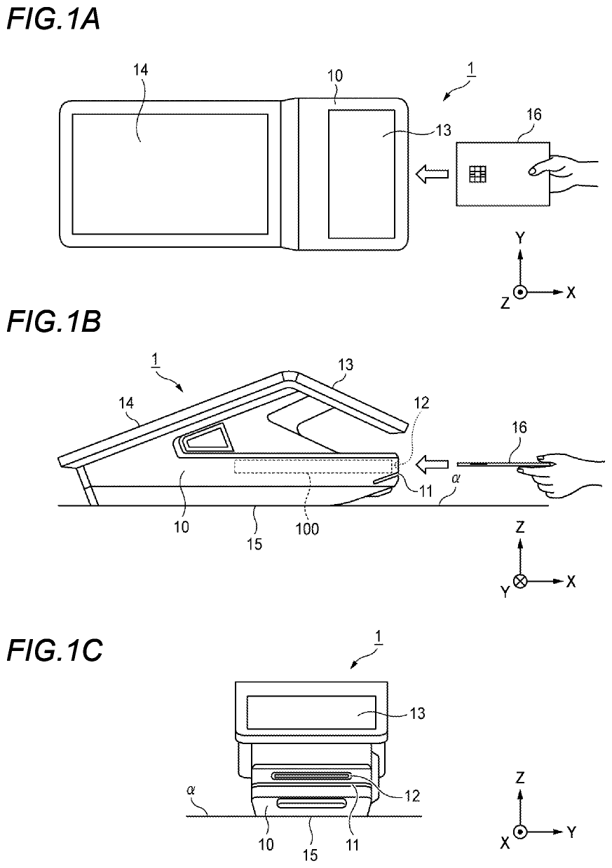

FIGS. 1A to 1C are views showing a configuration example of a settlement terminal according to the present embodiment, FIG. 1A is a top view, FIG. 1B is a side view, and FIG. 1C is a front view.

The settlement terminal 1 is a terminal corresponding to at least an electronic settlement, and is placed and used on a placement face a such as a counter of a store, for example. As shown in FIG. 1A, the settlement terminal 1 includes a substantially box-shaped housing 10.

The settlement terminal 1 may be a composite type settlement terminal capable of selecting a plurality of settlement methods by a user who performs electronic settlement. The settlement terminal 1 has a settlement mechanism for a user to select a settlement method and perform settlement. For example, as shown in FIGS. 1A to 1C, the settlement terminal 1 includes, as a settlement mechanism, a slot 11 for settlement of a magnetic card, a slot 12 for settlement of a contact IC card, and a touch face 13 for contact-less settlement, in this order from a bottom face 15 upward on one end side of the housing 10. In addition, the settlement terminal 1 includes an operation mechanism for an employee and the like of the store to perform settlement approval and the like. For example, as shown in FIG. 1B, the settlement terminal 1 includes, as an operation mechanism, an operation screen 14 on the other end side of the housing 10 (that is, on the opposite side of the settlement mechanism).

For example, a user inserts and slides a magnetic card into the slot 11 for magnetic card settlement. The user inserts a contact IC card 16 into the slot 12 for settlement of the contact IC card. The user holds a contact-less type IC card over the touch face 13 for contact-less settlement. The employee of the store operates the operation screen 14 of the settlement terminal 1 to determine the card settlement of the user.

The settlement terminal 1 includes an information processing apparatus 100 for performing settlement processing inside the housing 10. The information processing apparatus 100 which handles secret information such as settlement processing is required to have high security against physical attacks from the outside. That is, the information processing apparatus 100 is required to have high tamper proof. The information processing apparatus 100 having enhanced tamper proof will be described below.

For convenience of description, as shown in FIGS. 1A to 1C, an axis perpendicular to the bottom face 15 of the housing 10 is defined as a Z axis. An axis perpendicular to the Z axis (that is, parallel to the bottom face of the housing 10) from the operation mechanism side to the settlement mechanism side of the housing 10 is defined as the X axis. An axis orthogonal to the X axis and the Z axis is defined as a Y axis. For convenience of description, there is a case where the positive direction of the X axis is referred to as “front”, the negative direction of the X axis is referred to as “rear”, the positive direction of the Y axis is referred to as “right”, the negative direction of the Y axis is referred to as “left”, the positive direction of the Z axis is referred to as “upper”, and the negative direction of the Z axis is referred to as “lower”. Note that the expressions relating to these directions are used for convenience of description and are not intended to limit the posture of the structure in actual use.

### Information Processing Apparatus

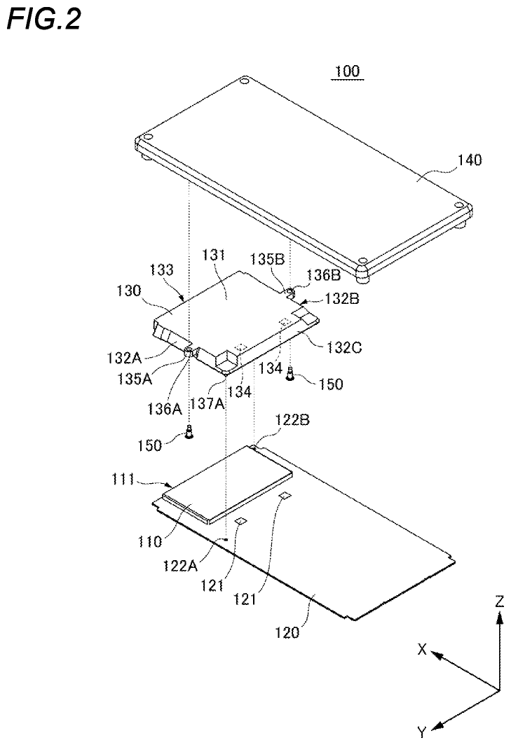

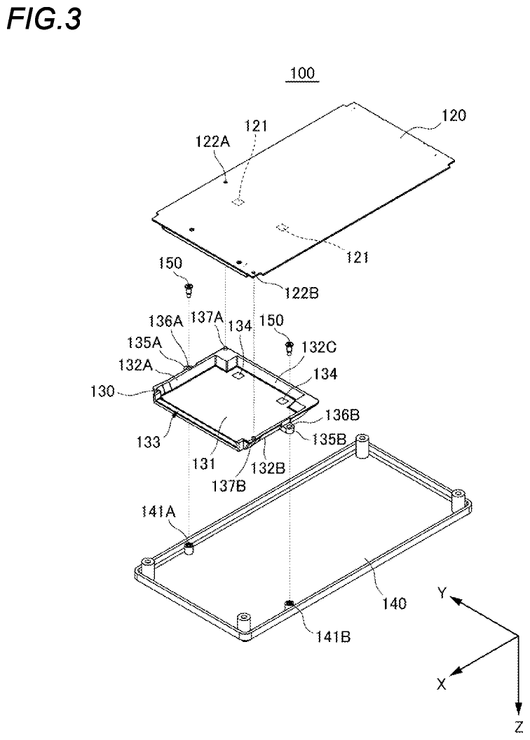

FIG. 2 is a view showing a configuration example of the information processing apparatus according to the present embodiment, and is an exploded perspective view of the information processing apparatus as viewed obliquely from above. FIG. 3 is a view showing a configuration example of the information processing apparatus according to the present embodiment, and is an exploded perspective view of the information processing apparatus as viewed obliquely from below. Next, the information processing apparatus will be described in detail with reference to FIGS. 2 and 3.

The information processing apparatus 100 includes a card connector 110, a circuit board 120, a protective cover 130, and a case 140.

The card connector 110 is a flat, substantially rectangular parallelepiped electronic device into which the IC card 16 is inserted. In the card connector 110, a card slot 111 as an insertion opening of the IC card 16 is formed on the front face (face in the positive direction of the X axis). The card slot 111 corresponds to the slot 12 for settlement of the contact type IC card in FIG. 1. The card connector 110 reads information of the inserted IC card 16, and transmits the read information to an IC chip (not shown) that performs settlement processing on the circuit board 120.

The circuit board 120 is, for example, a printed circuit board (PCB), and includes a printed wiring (not shown) and one or more electronic components on a top face. A card connector 110 is attached to the circuit board 120 as one of electronic components. An IC chip is attached to the circuit board 120 as an example of the electronic components. The tamper detection circuit (not shown) is attached to the circuit board 120 as one of the IC chips.

The tamper detection circuit monitors a signal flowing through a tamper detection wiring, which will be described later, and detects a disconnection and a short circuit of the tamper detection wiring. The tamper refers to a physical attack from the outside for the purpose of analyzing or falsifying secret information. An example of the tamper is a probing attack in which an elongated probe is inserted from the outside to analyze or falsify a signal. When a disconnection or a short circuit of the tamper detection wiring is detected, the tamper detection circuit performs a process for preventing the analysis and falsification of the secret information. For example, the tamper detection circuit stops the operation of the IC chip and erases information in the memory. As a result, the tamper by the attacker can be prevented.

The circuit board 120 includes a tamper detection wiring (not shown) for tamper detection with respect to the circuit board 120. The tamper detection wiring is electrically connected to the tamper detection circuit. The circuit board 120 has one or more board-side contacts 121. The circuit board-side contacts 121 are electrically connected to the tamper detection circuit.

The protective cover 130 is a component for covering and protecting the card connector 110 and the circuit board-side contacts 121 on the circuit board 120 from above. The protective cover 130 may have a substantially rectangular main face 131 parallel to the circuit board 120 and side faces 132A, 132B, and 132C extending in the direction of the circuit board 120 from three sides of the main face 131 respectively. Herein, a portion where the side faces 132A, 132B, and 132C in the protective cover 130 are not present is referred to as an opening portion 133. The opening portion 133 is formed so as not to interfere with the insertion of the IC card 16 of the card connector 110 in a case where the protective cover 130 is disposed on the top face of the circuit board 120.

The protective cover 130 includes cover-side contacts 134 on the bottom face of the main face 131 at positions in contact with the circuit board-side contacts 121 when disposed on the circuit board 120. The positions and number of the cover-side contacts 134 may be positions and numbers corresponding to one-to-one with the circuit board-side contacts 121.

The protective cover 130 includes a tamper detection wiring (not shown) on the entire face. The tamper detection wiring may be wired in a wiring pattern that covers the entire face of the protective cover 130 in a snake shape with signal stroke. The tamper detection wiring may be formed by a laser direct structuring (LDS) method. The tamper detection wiring is electrically connected to the cover-side contacts 134. Thus, the tamper detection wiring of the protective cover 130 is electrically connected to the tamper detection circuit through the cover-side contacts 134 and the circuit board-side contacts 121. Therefore, the tamper detection circuit can detect tamper with respect to the protective cover 130.

The case 140 is disposed to face the top face of the circuit board 120, and accommodates the circuit board 120 and the protective cover 130. Also, the case 140 may be engaged with a case (not shown) disposed to face the bottom face of the circuit board 120.

In the present embodiment, the protective cover 130 is attached to the bottom face of the case 140 without being attached to the circuit board 120. Thereby, when the case 140 is detached, the protective cover 130 attached to the case 140 is also detached together, and the cover-side contacts 134 of the protective cover 130 are separated from the circuit board-side contacts 121 of the circuit board 120. That is, the cover-side contacts 134 are in a contact-less state (that is, an electrical disconnected state) with the circuit board-side contacts 121. Therefore, the tamper detection circuit can detect the opening of the case 140. According to this configuration, both the tamper proof to the card connector 110 and the opening detection of the case 140 can be achieved by one protective cover 130. Therefore, it is not necessary to provide a new component for detecting the opening of the case 140, and the cost of the tamper proof can be reduced.

By reducing the area of the cover-side contacts 134 and the circuit board-side contacts 121, it is difficult for the attacker to bring the probe into contact with the cover-side contacts 134 and the circuit board-side contacts 121, and thus the tamper proof of the protective cover 130 is improved. However, reducing the area of the cover-side contacts 134 and the circuit board-side contacts 121 make it difficult to bring the cover-side contacts 134 and the circuit board-side contacts 121 into contact with each other due to dimensional tolerance and the like. In particular, as described above, in the configuration in which the protective cover 130 is attached to the case 140, the dimensional tolerance between the case 140 and the protective cover 130 and the dimensional tolerance between the protective cover 130 and the circuit board 120 are accumulated, so that there is a high possibility that the cover-side contacts 134 and the circuit board-side contacts 121 having a small area are not in contact with each other.

Therefore, in the following description, in a configuration in which the protective cover 130 is attached to the case 140 as described above, a configuration for reducing the possibility that the cover-side contacts 134 and the circuit board-side contacts 121 having a relatively small area will be not in contact with each other in will be described.

As shown in FIGS. 2 and 3, a right side face 132A of the protective cover 130 is provided with an extending portion 135A extending rightward, and a left side face 132B of the protective cover 130 is provided with an extending portion 135B extending leftward. Through holes 136A and 136B are formed in the extending portions 135A and 135B.

As shown in FIG. 3, on the bottom face of the case 140, a screw hole 141A is provided at a position corresponding to the through hole 136A of the protective cover 130, and a screw hole 141B is provided at a position corresponding to the through hole 136B of the protective cover 130.

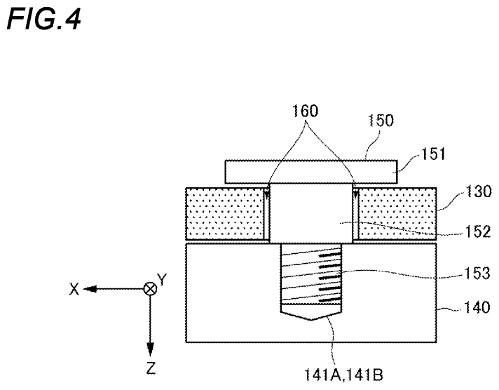

FIG. 4 is a view showing an example of attachment of the protective cover 130 to the case 140 by stepped screws 150. As shown in FIG. 4, the stepped screw 150 includes a head portion 151, a neck portion 152 in which no screw groove is formed, and a threaded groove portion 153 in which a screw groove is formed.

As shown in FIGS. 2 to 4, the protective cover 130 is inserted into the through holes 136A and 136B, and is attached to the case 140 by the stepped screws 150 screwed into screw holes 141A and 141B of the case 140.

As shown in FIG. 4, the diameter of the through holes 136A, 136B is greater than the diameter of the neck portion 152 of the stepped screw 150 and less than the diameter of the head portion 151 of the stepped screw 150. The difference 160 between the diameters of the through holes 136A, 136B and the diameter of the neck portion 152 of the stepped screw 150 may be greater than or equal to the dimensional tolerance between the protective cover 130 and the case 140. That is, the diameters of the through holes 136A, 136B may be a length that allows the dimensional tolerance between the protective cover 130 and the case 140.

Thus, the protective cover 130 is fixed in the upper-lower direction (Z axis direction), and can move freely in the direction (XY plane direction) parallel to the bottom face of the case 140 within a range of the difference 160 between the diameter of the through hole 136 of the protective cover 130 and the diameter of the neck portion 152 of the stepped screw 150.

In addition, as shown in FIGS. 2 and 3, the protective cover 130 includes two positioning pins 137A, 137B projecting downward on the sides of the side faces 132A, 132B which are brought into contact with the circuit board 120. For example, the two positioning pins 137A, 137B are provided at positions of substantially vertical angles as shown in FIGS. 2 and 3. In the top face of the circuit board 120, pin holes 122A, 122B are formed at positions corresponding to the positioning pins 137A, 137B of the protective cover 130. The positions of the two positioning pins 137A, 137B (and the pin holes 122A, 122B of the circuit board 120) are not limited to the above examples, and may be any position on the side which is brought into contact with the circuit board 120 of the protective cover 130.

According to the configuration of the circuit board 120, the protective cover 130, and the case 140 described above, the information processing apparatus 100 can be manufactured by the following manufacturing process.

(Step 1) The manufacturer aligns the positions of the through holes 136A, 136B of the protective cover 130 with the positions of the screw holes 141A, 141B of the case 140.

(Step 2) The manufacturer inserts the stepped screws 150 into the through holes 136A, 136 B and screws into the screw holes 141A, 141B to attach the protective cover 130 to the case 140.

(Step 3) The manufacturer inserts the positioning pins 137 of the protective cover 130 into the pin holes 122 of the circuit board 120 to assemble the circuit board 120, the protective cover 130, and the case 140.

In Step 3, since the protective cover 130 is movable in the parallel direction (XY plane direction) with respect to the bottom face of the case 140, the dimensional tolerance between the protective cover 130 and the case 140 is absorbed by the movement. Therefore, the area of the circuit board-side contacts 121 and the cover-side contacts 134 can be determined in consideration of dimensional tolerance between the protective cover 130 and the circuit board 120 without considering the dimensional tolerance between the protective cover 130 and the case 140. That is, the area of the circuit board-side contacts 121 and the cover-side contacts 134 can be reduced to the dimensional tolerance between the protective cover 130 and the circuit board 120.

According to the configuration described above, the information processing apparatus 100 with improved temper proof in which both the tamper proof to the card connector 110 and the opening detection of the case 140 can be achieved by one protective cover 130, and the area of the circuit board-side contacts 121 and the cover-side contacts 134 is reduced.

### Conclusion of Present Disclosure

The information processing apparatus (100) according to the present disclosure includes: a circuit board (120) having an electronic device, a first contact (121), and a pin hole (122A, 122B); a cover (130) that covers the electronic device and the first contact on the circuit board; and a case (140) that accommodates the circuit board and the cover. The cover includes a second contact (134) brought into contact with the first contact, a tampering detection wiring that is connected to the second contact and that is a wiring for tampering detection of the cover, a through hole (136A, 136B) that absorbs dimensional tolerance, and a positioning pin (137A, 137B) corresponding to the pin hole on the circuit board. The cover is attached to a back face of the case by inserting a predetermined screw into the through hole, and is positioned by inserting the positioning pin into the pin hole on the circuit board. The predetermined screw may be a stepped screw (150). The electronic device may be a card connector (110).

According to the above configuration, when the case (140) is removed, since the cover (130) is also removed together, both tamper to the electronic device (for example, the card connector (110)) and opening detection of the case can be achieved by one cover. In addition, since the cover is attached to the back face of the case by a predetermined screw (e.g., a stepped screw (150)) inserted into the through hole (136A, 136B) that allows dimensional tolerance, the cover is movable in a direction parallel to the back face of the case. Therefore, the dimensional tolerance between the cover and the case are absorbed by this movement, so the area of the circuit board-side contacts (121) and the cover-side contacts (134) can be reduced to dimensional tolerance between the cover and the circuit board. That is, the area of the circuit board-side contacts and the cover-side contacts can be reduced to increase the tamper proof.

Although the embodiments have been described above with reference to the accompanying drawings, the present disclosure is not limited to such examples. Those skilled in the art will recognize that various changes, modifications, substitutions, additions, deletions, and equivalents may be made within the scope of the appended claims, and are understood to belong to the technical scope of the present disclosure. In addition, constituent elements in the above-described embodiments may be arbitrarily combined within a range not departing from the gist of the invention.

### INDUSTRIAL APPLICABILITY

The technology of the present disclosure is useful in a device that is required to be tamperproof.

1. An information processing apparatus comprising:
a circuit board that has an electronic device, a first contact, and a pin hole;
a cover that covers the electronic device and the first contact on the circuit board; and
a case that accommodates the circuit board and the cover, wherein
the cover includes:
a second contact that is in contact with the first contact;
a tampering detection wiring that is connected to the second contact and that is a wiring for tampering detection of the cover;
a through hole that absorbs dimensional tolerance; and
a positioning pin that corresponds to the pin hole of the circuit board, and
the cover is attached to a back face of the case by inserting a predetermined screw into the through hole, and is positioned by inserting the positioning pin into the pin hole on the circuit board.

2. The information processing apparatus according to claim 1, wherein
the predetermined screw is a stepped screw.

3. The information processing apparatus according to claim 1, wherein
the electronic device is a card connector.

4. A method of manufacturing an information processing apparatus, the information processing apparatus including:
a circuit board that has an electronic device, a first contact, and a pin hole;
a cover that covers the electronic device and the first contact on the circuit board;
a second contact that is provided on the cover and is contact with the first contact;
a tamper detection wiring that is provided on the cover and that is a wiring for tampering detection connected to the second contact;
a through hole that is provided on the cover and that absorbs dimensional tolerance;
a positioning pin that is provided on the cover and that corresponds to the pin hole of the circuit board; and
a case that accommodates the circuit board and the cover,
the method comprising:
inserting the positioning pin into the pin hole of the circuit board; and
attaching the cover to a back face of the case by inserting a predetermined screw into the through hole.
